(19) United States
(12) Patent Application Publication
(10) Pub. No.: US 2023/0170337 A1
(43) Pub. Date: Jun. 1, 2023

(54) TRANSIENT-SUBSTRATE ASSEMBLY AND MANUFACTURING METHOD THEREOF

(71) Applicant: CHONGQING KOKA PHOTOELECTRIC TECHNOLOGY RESEARCH INSTITUTE CO., LTD., Chongqing (CN)

(72) Inventors: Feifan MA, Chongqing (CN); Guangchao DAI, Chongqing (CN)

(21) Appl. No.: 18/152,496

(22) Filed: Jan. 10, 2023

Related U.S. Application Data
(63) Continuation of application No. PCT/CN2021/134482, filed on Nov. 30, 2021.

(51) Int. Cl. H01L 25/075; H01L 33/38; H01L 33/62; H01L 33/00

(52) U.S. Cl. CPC H01L 25/0753; H01L 33/005; H01L 33/62; H01L 33/382

(57) ABSTRACT

A transient-substrate assembly and a manufacturing method thereof are provided. The transient-substrate assembly includes a first substrate, a supporting layer, and light-emitting chips. The supporting layer is fixed on the first substrate, and defines multiple receiving cavities isolated from one another and at least one opening extending through a top surface and a bottom surface of the supporting layer. The multiple receiving cavities each have an opening away from the first substrate. The light-emitting chips are respectively disposed in the multiple receiving cavities. The light-emitting chip is located at a bottom of a corresponding receiving cavity and attached to the supporting layer. A side surface of the light-emitting chip and a side wall of the corresponding receiving cavity are separated by a gap.

### CROSS-REFERENCE TO RELATED APPLICATION(S)

This application is a continuation of International Application No. PCT/CN2021/134482, filed Nov. 30, 2021, the disclosure of which is hereby incorporated by reference in its entirety.

### TECHNICAL FIELD

This application relates to the field of light-emitting chips, and more particularly to a transient-substrate assembly and a manufacturing method thereof.

### BACKGROUND

Light-emitting diodes (LED) have advantages of low power consumption, environmental friendliness, long service life, etc., and therefore, the LEDs are likely to replace incandescent lamps, fluorescent lamps, and other traditional lighting fixtures and become increasingly popular in the future.

Micro LEDs, as a new display technology, have advantages of high brightness, low delay, long service life, wide viewing angle, high contrast, etc., and have become a development direction of LEDs. Currently, a manufacturing process of micro LEDs relates to chip transferring. During the chip transferring, a large number of light-emitting chips need to be stripped off from a substrate and then transferred, and only light-emitting chips stripped and transferred can be attached onto a specified circuit.

Currently, during transferring of light-emitting chips, the light-emitting chips need to be transferred onto another substrate from a substrate. However, positions of the light-emitting chips are extremely easy to change during stripping and transferring of the light-emitting chips, causing relatively low yield of light-emitting chips. Therefore, how to improve yield of light-emitting chips during transferring has become a problem to-be-solved.

### SUMMARY

The disclosure provides a transient-substrate assembly. The transient-substrate assembly includes a first substrate, a supporting layer, and light-emitting chips. The supporting layer is fixed on the first substrate, and defines multiple receiving cavities isolated from one another and at least one opening that extends through a top surface and a bottom surface of the supporting layer. The multiple receiving cavities each have an opening away from the first substrate. The light-emitting chips are respectively disposed in the multiple receiving cavities, where the light-emitting chip is located at a bottom of a corresponding receiving cavity and attached to the supporting layer, and a side surface of the light-emitting chip and a side wall of the corresponding receiving cavity are separated by a gap.

The disclosure further provides a manufacturing method of a transient-substrate assembly. The manufacturing method of the transient-substrate assembly includes the following. A first substrate of the transient-substrate assembly is provided. The first substrate is fixed onto a supporting layer of the transient-substrate assembly, where the supporting layer defines multiple receiving cavities isolated from one another, a surface of the supporting layer fixed on the first substrate is away from an opening of each of the multiple receiving cavities, and the supporting layer further defines at least one opening extending through a top surface and a bottom surface of the supporting layer. Light-emitting chips of the transient-substrate assembly are placed into the multiple receiving cavities respectively, where the light-emitting chip placed is located at a bottom of a corresponding receiving cavity and attached to the supporting layer, and a side surface of the light-emitting chip and a side wall of the corresponding receiving cavity are separated by a gap.

### BRIEF DESCRIPTION OF THE DRAWINGS

FIG. 1 is a schematic structural diagram illustrating an array-substrate assembly provided in implementations of the disclosure.

FIG. 2 is a schematic structural diagram illustrating an array-substrate assembly provided in other implementations of the disclosure.

FIG. 3 is a schematic structural diagram illustrating an array-substrate assembly provided in other implementations of the disclosure.

FIG. 4 is a schematic structural diagram illustrating a transient-substrate assembly provided in implementations of the disclosure.

FIG. 5 is a schematic structural diagram illustrating a transient-substrate assembly provided in other implementations of the disclosure.

FIG. 6 is a schematic structural diagram illustrating a transient-substrate assembly provided in other implementations of the disclosure.

FIG. 7 is a schematic flow chart illustrating a manufacturing method of a transient-substrate assembly provided in implementations of the disclosure.

FIG. 8 is a schematic flow chart illustrating operations before removing a sacrificial layer in a manufacturing method of a transient-substrate assembly provided in implementations of the disclosure.

FIG. 9 is a schematic diagram illustrating products corresponding to operations before removing a sacrificial layer in a manufacturing method of a transient-substrate assembly provided in implementations of the disclosure.

FIG. 10 is a schematic diagram illustrating products corresponding to operations in a manufacturing method of a transient-substrate assembly provided in implementations of the disclosure.

Reference signs: 110 - second substrate, 120 - light-emitting chip, 121 - electrode, 130 - sacrificial layer, 131 - groove, 140 - supporting layer, 141 - side wall, 142 - receiving cavity, 150 - opening, 151 - first opening, 152 - second opening, 210 - first substrate.

### DETAILED DESCRIPTION

In order to facilitate understanding of the disclosure, a detailed description will now be given with reference to relevant accompanying drawings. The accompanying drawings illustrate some exemplary examples of implementations of the disclosure. However, the disclosure can be implemented in many different forms and is not limited to the implementations described herein. On the contrary, these implementations are provided for a more thorough and comprehensive understanding of the disclosure.

Unless otherwise defined, all technical and scientific terms used herein have the same meaning as commonly understood by those skilled in the art of the disclosure. The terms in the disclosure are for the purpose of describing implementations only and not intended to limit the disclosure.

In the related art, with development of mini light-emitting diode (LED) and micro LED technology, manufactured LED light-emitting chips 120 are getting smaller in size, and the number of manufactured LED light-emitting chips 120 is increasing, and thus requirements on precision of manufacturing light-emitting chips 120 and requirements on security and yield of transferring of light-emitting chips 120 become higher.

In view of the above deficiencies of the related art, the disclosure provides a transient-substrate assembly and a manufacturing method thereof, which aim to solve a problem of relatively low yield of light-emitting chips during transferring in the related art.

The disclosure provides a transient-substrate assembly. The transient-substrate assembly includes a first substrate, a supporting layer, and light-emitting chips. The supporting layer is fixed on the first substrate, and defines multiple receiving cavities isolated from one another and at least one opening extending through a top surface and a bottom surface of the supporting layer. The multiple receiving cavities each have an opening away from the first substrate. The light-emitting chips are respectively disposed in the multiple receiving cavities, where the light-emitting chip is located at a bottom of a corresponding receiving cavity and attached to the supporting layer, and a side surface of the light-emitting chip and a side wall of the corresponding receiving cavity are separated by a gap.

According to the above transient-substrate assembly, the supporting layer is disposed on the first substrate and defines the multiple receiving cavities isolated from one another, and the light-emitting chips are placed in their respective receiving cavities. Since the light-emitting chip is placed in a corresponding receiving cavity of the supporting layer, the light-emitting chip can be constrained to move in the corresponding receiving cavity. During moving of the transient-substrate assembly, it can ensure that a range of moving of the light-emitting chip is in an allowable range of a process error, thereby improving a success rate of transferring the light-emitting chips, and thus improving yield of transferring the light-emitting chips.

In some implementations, the supporting layer is any one of: a silicon-dioxide layer, a silicon-nitride layer, or a metal layer.

In some implementations, the opening defined on the supporting layer includes at least one of: a first opening defined on the supporting layer that corresponds to a bottom of each of the plurality of receiving cavities; or a second opening defined on the supporting layer between two adjacent light-emitting chips.

In some implementations, the first opening is between two electrodes of the light-emitting chip.

In some implementations, the light-emitting chips each have a top surface and a bottom surface opposite to the top surface, electrodes of the light-emitting chip are disposed on the bottom surface of the light-emitting chip and attached to the supporting layer.

In some implementations, the light-emitting chips each have a top surface and a bottom surface opposite to the top surface, electrodes of the light-emitting chip are disposed on the bottom surface of the light-emitting chip, the top surface of the light-emitting chip is attached to the supporting layer, and the plurality of receiving cavities on the first substrate are in one-to-one correspondence with chip bonding areas on a circuit board.

In some implementations, a height of each of the plurality of receiving cavities is less than or equal to a height of each of the light-emitting chips.

The disclosure further provides a manufacturing method of a transient-substrate assembly. The manufacturing method of the transient-substrate assembly includes the following. A first substrate of the transient-substrate assembly is provided. The first substrate is fixed onto a supporting layer of the transient-substrate assembly, where the supporting layer defines multiple receiving cavities isolated from one another, a surface of the supporting layer fixed on the first substrate is away from an opening of each of the multiple receiving cavities, and the supporting layer further defines at least one opening extending through a top surface and a bottom surface of the supporting layer. Light-emitting chips of the transient-substrate assembly are placed into the multiple receiving cavities respectively, where the light-emitting chip placed is located at a bottom of a corresponding receiving cavity and attached to the supporting layer, and a side surface of the light-emitting chip and a side wall of the corresponding receiving cavity are separated by a gap.

According to the transient-substrate assembly manufactured with the above manufacturing method, the supporting layer is fixedly disposed on the first substrate and defines the multiple receiving cavities isolated from one another, and the light-emitting chips are placed in their respective receiving cavities. Since the light-emitting chip is placed in a corresponding receiving cavity of the supporting layer, the light-emitting chip can be constrained to move in the corresponding receiving cavity. During moving of the transient-substrate assembly, it can ensure that a range of moving of the light-emitting chip is in an allowable range of a process error, thereby improving a success rate of transferring the light-emitting chips, and thus improving yield of transferring the light-emitting chips.

In some implementations, fixing the first substrate onto the supporting layer of the transient-substrate assembly includes: disposing fixedly an adhesive layer onto the first substrate; and fixing the first substrate onto the supporting layer through the adhesive layer.

In some implementations, before fixing the first substrate onto the supporting layer of the transient-substrate assembly, the method further includes: removing a sacrificial layer among the supporting layer, the light-emitting chips, and a second substrate, wherein the supporting layer is separated from the light-emitting chips and the second substrate through the sacrificial layer.

The sacrificial layer among the supporting layer, the light-emitting chips, and the second substrate is removed before the first substrate is fixed onto the supporting layer. The sacrificial layer is provided to protect the light-emitting chips under the sacrificial layer when the supporting layer is generated. Moreover, a specified structure can be formed on the supporting layer by processing a surface of the sacrificial layer, and the sacrificial layer is also functioned as a buffer, to better protect the light-emitting chips during moving.

In some implementations, removing the sacrificial layer includes at least one of: removing the sacrificial layer by irradiating a preset electromagnetic wave; removing the sacrificial layer by heating the sacrificial layer to a preset temperature; or removing the sacrificial layer by using a preset chemical reagent.

In some implementations, the sacrificial layer defines a groove between two adjacent light-emitting chips, and a side wall of two adjacent receiving cavities is filled in at least part of the groove.

In some implementations, a thickness of the sacrificial layer is greater than or equal to 0.1 µm and less than or equal to 100 µm.

In some implementations, on condition that electrodes of the light-emitting chip are between the supporting layer and the light-emitting chip, a thickness of the sacrificial layer is greater than a height of each of the electrodes.

In some implementations, before removing the sacrificial layer, the method further includes: providing the second substrate; disposing the light-emitting chips onto the second substrate; forming the sacrificial layer on the light-emitting chips and a surface of the second substrate disposed with the light-emitting chips; forming the supporting layer on the sacrificial layer; and defining the at least one opening on the supporting layer.

In some implementations, after fixing the first substrate onto the supporting layer of the transient-substrate assembly, the method further includes: flipping over the second substrate and the first substrate.

In some implementations, placing the light-emitting chips of the transient-substrate assembly into the plurality of receiving cavities respectively includes: placing the light-emitting chip into a corresponding receiving cavity by stripping off the light-emitting chip from the second substrate after the second substrate and the first substrate are flipped over, wherein the light-emitting chip placed is attached to a bottom of the corresponding receiving cavity.

In some implementations, the opening defined on the supporting layer includes at least one of: a first opening defined on the supporting layer that corresponds to a bottom of each of the plurality of receiving cavities; or a second opening defined on the supporting layer between two adjacent light-emitting chips.

In some implementations, the first opening is between two electrodes of the light-emitting chip.

In some implementations, the light-emitting chips each have a top surface and a bottom surface opposite to the top surface, electrodes of the light-emitting chip are disposed on the bottom surface of the light-emitting chip and attached to the supporting layer.

Based on the above, a solution capable of solving the above technical problem is provided in the disclosure, which will be explained in detail in the following implementations.

An array-substrate assembly is provided in implementations of the disclosure. Manufacturing of micron-level light-emitting chips 120 such as mini LED chips or micro LED chips can adopt an array-substrate assembly, and manufacturing of normal-sized (e.g., > 50 µm) LED chips or large-sized LED chips can also adopt an array-substrate assembly. The array-substrate assembly is an intermediate assembly for manufacturing the LED chips, and is also an optional assembly for manufacturing a transient-substrate assembly of the disclosure. A structure of the array-substrate assembly of these implementations is improved, which allows the array-substrate assembly to better protect and fix light-emitting chips 120 therein during transferring and transportation, thereby improving yield.

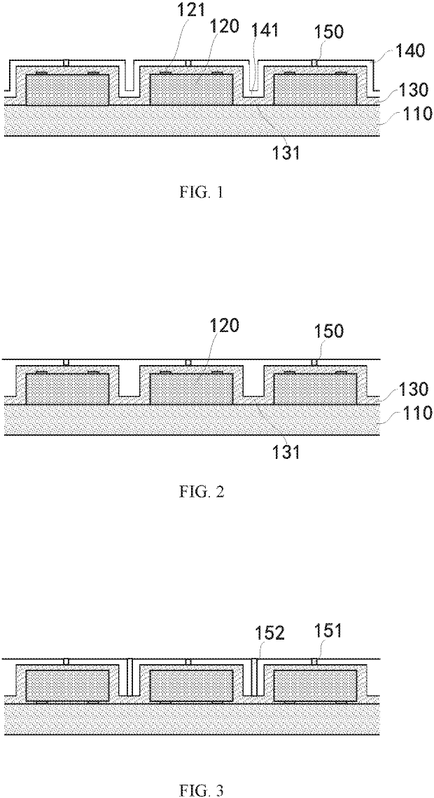

Referring to FIG. 1, FIG. 1 is a schematic diagram illustrating a partial cross section of the array-substrate assembly of these implementations. The array-substrate assembly includes a second substrate 110, multiple light-emitting chips 120 disposed on the second substrate 110, a sacrificial layer 130, and a supporting layer 140. The sacrificial layer 130 is disposed on the second substrate 110 and covered on the multiple light-emitting chips 120, and defines a groove 131 between two adjacent light-emitting chips 120. The supporting layer 140 is disposed on the second substrate 110 and covered on the sacrificial layer 130, is filled in at least part of the groove 131, and defines at least one opening 150 in communication with the sacrificial layer 130.

In these implementations, the second substrate 110 is configured to carry the multiple light-emitting chips 120. Optionally, the second substrate 110 includes, but is not limited to, a sapphire substrate, a gallium-selenide substrate, or a silicon substrate. The multiple light-emitting chips 120 are fixed on the second substrate 110. The multiple light-emitting chips 120 are generally arranged on the second substrate 110 in an array according to a certain rule. The light-emitting chips 120 of implementations of the disclosure include, but are not limited to, light-emitting chips 120 that are transferred onto the second substrate 110, or light-emitting chips 120 that are grown directly on the second substrate 110.

In implementations of the disclosure, the light-emitting chips 120 include, but are not limited to, multiple-color light-emitting chips 120 (e.g., red-green-blue (RGB) light-emitting chips 120), or single-color light-emitting chips 120. Generally, the light-emitting chip 120 further includes two electrodes 121. In FIG. 1, the two electrodes 121 are located at a top of the light-emitting chip 120. In other implementations, the two electrodes 121 may be located at a bottom of the light-emitting chip 120 illustrated in FIG. 3, a side surface of the light-emitting chip 120, etc., which is not limited in the disclosure.

In these implementations, the second substrate 110 and the light-emitting chips 120 are completely covered by the sacrificial layer 130. The sacrificial layer 130 defines a groove 131 between two adjacent light-emitting chips 120, and each of the light-emitting chips 120 is surrounded by grooves 131. A manner for defining the groove 131 on the sacrificial layer 130 includes, but is not limited to, naturally forming the groove 131 between two adjacent light-emitting chips when depositing the sacrificial layer 130, or forming the groove 131 on the sacrificial layer 130 through etching. In these implementations, a thickness of the sacrificial layer 130 needs to meet certain requirements. For example, if the electrodes 121 of the light-emitting chip 120 are located at the top or the side surface of the light-emitting chip 120, the sacrificial layer 130 needs to have a thickness that allows the electrodes 121 to be completely covered.

In these implementations, the supporting layer 140 is completely covered on the sacrificial layer 130. The supporting layer 140 is filled in at least part of the groove 131 of the sacrificial layer 130, to form a concave structure (as side walls 141) between two adjacent light-emitting chips 120. In these implementations, the material of the supporting layer 140 is different from that of the sacrificial layer 130, and the supporting layer 140 is required to have a certain support force and a certain structural strength, to protect and fix the light-emitting chips 120. It can be understood that, in these implementations, a part of the supporting layer 140 corresponding to the groove 131 is concave to form a concave structure as side walls 141, where the concave structure may be a solid structure illustrated in FIG. 2 or a hollow structure illustrated in FIG. 1. The supporting layer 140 is not necessarily filled in the whole groove 131, and may be filled in only part of the groove 131 in some cases.

In some implementations, the supporting layer 140 further defines the opening 150 in communication with the sacrificial layer 130. The opening 150 is mainly used to discharge residuals of the sacrificial layer 130 through the opening 150 when removing the sacrificial layer 130.

In these implementations, the sacrificial layer 130 may be any one of: a photolytic adhesive layer, a pyrolytic adhesive layer, or a chemical debonding layer.

Since the sacrificial layer 130 is required to be removed in a subsequent process, the sacrificial layer 130 is generally made of an organic adhesive capable of being removed. Therefore, the sacrificial layer 130 may be a structural layer with the above characteristics, where the photolytic adhesive layer can be removed under irradiation of a specific-wavelength electromagnetic wave or ray, the pyrolytic adhesive layer can be removed under a specific temperature, and the chemical debonding layer can be etched or dissolved by a specific chemical solvent. It can be understood that, in actual applications, selection of the sacrificial layer 130 requires that removal of the sacrificial layer 130 does not affect performances of other structures in the assembly.

In some implementations, the opening 150 includes at least one of: a first opening 151 defined on the supporting layer 140 above the light-emitting chip 120, or a second opening 152 defined on the supporting layer 140 between two adjacent light-emitting chips 120.

Referring to FIG. 3, the opening 150 on the supporting layer 140 may be the first opening 151 above the light-emitting chip 120 or the second opening 152 between two adjacent light-emitting chips 120, or may include the first opening 151 and the second opening 152. It can be understood that, the first opening 151 is defined above the light-emitting chip 120, which does not mean that the first opening 151 is defined above each of all the light-emitting chips 120. In other words, the first opening 151 is not required to be defined above any light-emitting chip 120. In some implementations, no first opening 151 is defined above some of all the light-emitting chips 120, while the first opening 151 is defined above each of remaining light-emitting chips 120. The second opening 152 is similar to the first opening 151 in terms of quantity and defined position, and thus, the second opening 152 is not required to be defined between any two adjacent light-emitting chips 120.

In some implementations, the first opening 151 is defined on the supporting layer 140 above each light-emitting chip 120 and is between the two electrodes 121 of the light-emitting chip 120.

If the two electrodes 121 of the light-emitting chip 120 are located at the top or the bottom of the light-emitting chip 120, the first opening 151 is generally defined between the two electrodes 121. Such arrangement of the first opening 151 is conducive to uniform removal of the sacrificial layer 130 when removed, thereby improving a removing speed of the sacrificial layer 130 and reducing a probability of residuals of the sacrificial layer 130. It is to be noted that, if the two electrodes 121 of the light-emitting chip 120 are disposed at the top of the light-emitting chip 120, the first opening 151 is usually defined at a position that avoids the two electrodes 121 as much as possible, to avoid reducing yield due to damage to the two electrodes 121.

In some implementations, the thickness of the sacrificial layer 130 is greater than or equal to 0.1 µm and less than or equal to 100 µm.

In actual applications, the thickness of the sacrificial layer 130 is required to be comprehensively determined according to a size of the light-emitting chip 120, a size of a gap between two adjacent light-emitting chips 120, and a size of each of the two electrodes 121. In some implementations, thicknesses of different parts of the sacrificial layer 130 are different (i.e., the sacrificial layer 130 has a non-uniform thickness). For example, a part of the sacrificial layer 130 covered on the top of the light-emitting chip 120 is relatively thick, and a part of the sacrificial layer 130 covered on the second substrate 110 and a side surface of the light-emitting chip 120 is relatively thin. As an example, if the thickness of the light-emitting chip 120 is 1 µm, the size of the gap between two adjacent light-emitting chips 120 is 1 µm, and the two electrodes 121 are located at the top of the light-emitting chip 120 and have a height of 0.2 µm, the thickness of the sacrificial layer 130 can be set to 0.3 µm, to ensure that the electrodes 121 can be completely covered and the groove 131 can be defined between two adjacent light-emitting chips 120. As another example, if the thickness of the light-emitting chip 120 is 10 µm, the size of the gap between two adjacent light-emitting chips 120 is 5 µm, and the two electrodes 121 are located at the top of the light-emitting chip 120 and have a height of 3 µm, a thickness of the sacrificial layer 130 on the light-emitting chip 120 can be set to 4 µm, and thicknesses of other parts of the sacrificial layer 130 can be set to 1.5 µm, to ensure that the electrodes 121 can be completely covered and the groove 131 can be defined between two adjacent light-emitting chips 120.

The array-substrate assembly is provided in these implementations. The array-substrate assembly includes the second substrate 110, the multiple light-emitting chips 120 disposed on the second substrate 110, the sacrificial layer 130, and the supporting layer 140. The sacrificial layer 130 is disposed on the second substrate 110 and covered on the multiple light-emitting chips 120, and defines the groove 131 between two adjacent light-emitting chips 120. The supporting layer 140 is disposed on the second substrate 110 and covered on the sacrificial layer 130, is filled in at least part of the groove 131, and defines at least one opening 150 in communication with the sacrificial layer 130. According to the array-substrate assembly of these implementations, the sacrificial layer 130 is disposed on the second substrate 110 and the multiple light-emitting chips 120, the supporting layer 140 is disposed on the sacrificial layer 130, the sacrificial layer 130 serves as a buffer, and the supporting layer 140 plays a role in supporting and fixing, to ensure security of the light-emitting chips 120 during moving and transportation of the array-substrate assembly, thereby improving product yield. Moreover, the supporting layer 140 defines the opening 150 in communication with the sacrificial layer 130, which is conducive to discharging generated residuals through the opening 150 during subsequent removal of the sacrificial layer 130.

### In Other Implementations of the Disclosure

In the related art, with development of mini LED and micro LED technology, manufactured LED light-emitting chips 120 are getting smaller in size, and the number of manufactured LED light-emitting chips 120 is increasing, and thus requirements on precision of manufacturing light-emitting chips 120 and requirements on security and yield of transferring of light-emitting chips 120 become higher.

For solving the above technical problem, a transient-substrate assembly is provided in other implementations of the disclosure. Manufacturing of micron-level light-emitting chips 120 such as mini LED chips or micro LED chips can adopt a transient-substrate assembly, and manufacturing of normal-sized (e.g., > 50 µm) LED chips or large-sized LED chips can also adopt a transient-substrate assembly. The transient-substrate assembly is an intermediate assembly for manufacturing the LED chips. A structure of the transient-substrate assembly of these implementations is improved, which allows the transient-substrate assembly to better protect and fix light-emitting chips 120 therein during transferring and transportation, thereby improving yield.

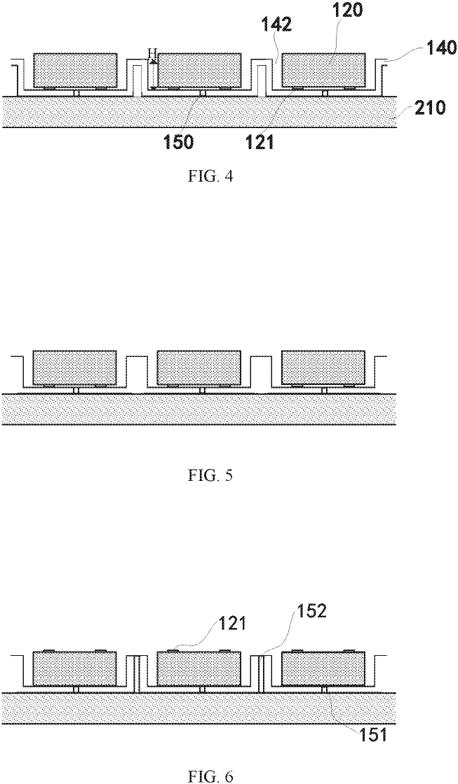

Referring to FIG. 4, FIG. 4 is a schematic diagram illustrating a partial cross section of the transient-substrate assembly of these implementations. The transient-substrate assembly includes a first substrate 210, a supporting layer 140, and light-emitting chips 120. The supporting layer 140 is fixed on the first substrate 210, and defines multiple receiving cavities 142 isolated from one another and at least one opening 150 that extends through a top surface and a bottom surface of the supporting layer 140. The multiple receiving cavities 142 each have an opening away from the first substrate 210. The light-emitting chips 120 are respectively disposed in the multiple receiving cavities 142, where the light-emitting chip 120 is located at a bottom of a corresponding receiving cavity 142 and attached to the supporting layer 140, and a side surface of the light-emitting chip 120 and a side wall 141 of the corresponding receiving cavity 142 are separated by a gap.

It should be noted that, in the disclosure, unless specifically stated, terms indicating an orientation or positional relationship, such as the “top” or the “bottom”, are based on an orientation or positional relationship illustrated in the accompanying drawings, and are intended for ease of description of the disclosure, rather than indicating or implying that a device or an element must have a particular orientation, be constructed and operate in a particular orientation, and therefore cannot be construed as limiting of the disclosure. As an example, the bottom of the receiving cavity refers to a part of the receiving cavity opposite to the opening of the receiving cavity. As another example, the top surface and the bottom surface of the light-emitting chip are surfaces of the light-emitting chip other than four side surfaces, and are opposite to each other.

In addition, it should be noted that, light-emitting chips are disposed in receiving cavities in a one-to-one correspondence relationship.

In these implementations, the first substrate 210 is used to fix the supporting layer 140. The first substrate 210 includes, but is not limited to, a sapphire substrate, a gallium-selenide substrate, or a silicon substrate. In implementations of the disclosure, the supporting layer 140 may be transferred onto the first substrate 210 through a manner including, but not limited to, transferring.

In implementations of the disclosure, the light-emitting chips 120 include, but are not limited to, multiple-color light-emitting chips 120 (e.g., RGB light-emitting chips 120), or single-color light-emitting chips 120. Generally, the light-emitting chip 120 further includes two electrodes 121. In FIG. 4, the two electrodes 121 are located at a bottom of the light-emitting chip 120. In other implementations, the two electrodes 121 may be located at a top of the light-emitting chip 120, a side surface of the light-emitting chip 120, or the like, which is not limited in the disclosure.

In these implementations, the supporting layer 140 is fixed on the first substrate 210 and defines the multiple receiving cavities 142 isolated from one another, where the receiving cavity 142 is configured to receive the light-emitting chip 120. The supporting layer 140 further defines at least one opening 150 that extends through the top surface and the bottom surface of the supporting layer 140. In the implementation, the supporting layer 140 is used to fix the light-emitting chip 120, and the receiving cavity 142 is used to receive the light-emitting chip 120, to avoid occurrence of relatively large displacement of the light-emitting chip 120 and protect the light-emitting chip 120, and therefore, the supporting layer 140 is required to have a certain support force and a certain structural strength.

In these implementations, the supporting layer 140 further defines the multiple receiving cavities 142 isolated from one another, where the receiving cavity 142 is configured to receive the light-emitting chip 120. The light-emitting chip 120 is attached to the bottom of the corresponding receiving cavity 142 under action of gravity. The side surface of the light-emitting chip 120 and the internal side wall 141 of the corresponding receiving cavity 142 are separated by the gap, to facilitate picking the light-emitting chip 120 out from the corresponding receiving cavity 142. It can be understood that, a side wall(s) 141 between two adjacent receiving cavities 142 may be a side wall(s) 141 of a hollow structure illustrated in FIG. 4 and may also be a side wall(s) 141 of a solid structure illustrated in FIG. 5.

In these implementations, the opening 150 on the supporting layer 140 belongs to a notch for auxiliary processing, and is a through hole for facilitating removal of the sacrificial layer 130 between the light-emitting chip 120 and the supporting layer 140 during production, and therefore, the opening needs to extend through the top surface and the bottom surface of the supporting layer 140.

In these implementations, the supporting layer 140 is any one of: a silicon-dioxide layer, a silicon-nitride layer, or a metal layer.

In these implementations, the supporting layer 140 is required to have a certain support force and a certain structural strength, and therefore the supporting layer 140 may be a structural layer made of the above materials. It can be understood that, an optional metal contained in the metal layer includes, but is not limited to, copper, aluminum, titanium, and other metal alloys.

In these implementations, the opening 150 includes at least one of: a first opening 151 defined on the supporting layer 140 that corresponds to a bottom of each of the multiple receiving cavities 142, or a second opening 152 defined on the supporting layer 140 between two adjacent light-emitting chips 120.

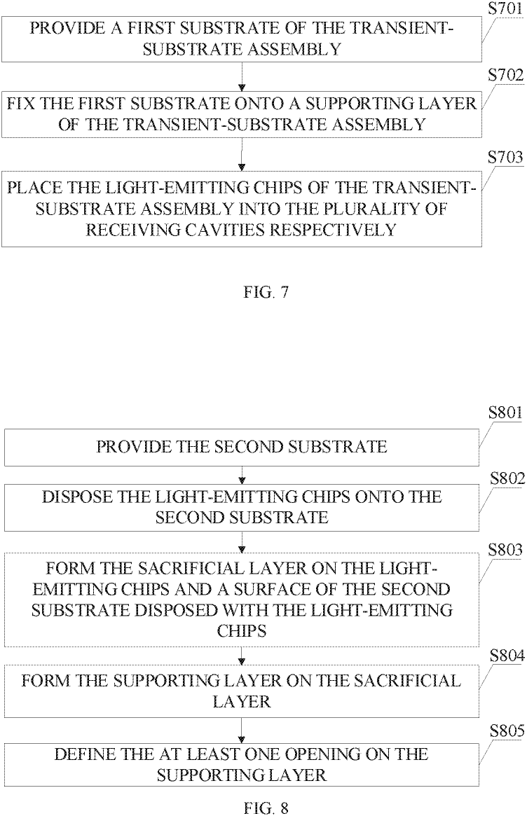

Referring to FIG. 6, the opening 150 on the supporting layer 140 may be the first opening 151 at the bottom of the receiving cavity 142 or the second opening 152 in the side wall 141 between two adjacent receiving cavities 142, or may include the first opening 151 and the second opening 152. It can be understood that, the first opening 151 is defined at the bottom of the receiving cavity 142, which does not mean that the first opening 151 is defined at the bottom of each of all the receiving cavities 142. In other words, the first opening 151 is not required to be defined at the bottom of any receiving cavity 142. In some implementations, no first opening 151 is defined at the bottom of each of some of all the receiving cavities 142, while the first opening 151 is defined at the bottom of each of remaining receiving cavities 142. The second opening 152 is similar to the first opening 151 in terms of quantity and defined position, and thus, the second opening 152 is not required to be defined in the side wall 141 between any two adjacent receiving cavities 142.

In these implementations, the first opening 151 is defined on the supporting layer 140 that corresponds to the bottom of each of the multiple receiving cavities 142, and the first opening 151 is defined between the two electrodes 121 of the light-emitting chip 120.

If the two electrodes 121 of the light-emitting chip 120 are located at the top or the bottom of the light-emitting chip 120, the first opening 151 is generally defined between the two electrodes 121. Such arrangement of the first opening 151 is conducive to uniform removal of the sacrificial layer 130 when removed, thereby improving a removing speed of the sacrificial layer 130 and reducing a probability of residuals of the sacrificial layer 130. It is to be noted that, if the two electrodes 121 of the light-emitting chip 120 are disposed at the bottom of the corresponding receiving cavity 142, the first opening 151 is usually defined at a position that avoids the two electrodes 121 as much as possible, to avoid reducing yield due to damage to the two electrodes 121.

In these implementations, the light-emitting chips 120 each have a top surface and a bottom surface opposite to the top surface, and electrodes 121 of the light-emitting chip 120 are disposed on the bottom surface of the light-emitting chip 120 and attached to the supporting layer 140.

Referring to FIG. 4 and FIG. 5, the electrodes 121 of the light-emitting chip 120 are disposed on the bottom surface of the light-emitting chip 120. When the light-emitting chip 120 is placed in the corresponding receiving cavity 142, the electrodes 121 are attached to a bottom of the corresponding receiving cavity 142 and contacted with the supporting layer 140.

In these implementations, the light-emitting chips 120 each have a top surface and a bottom surface opposite to the top surface, electrodes 121 of the light-emitting chip 120 are disposed on the bottom surface of the light-emitting chip 120, the top surface of the light-emitting chip 120 is attached to the supporting layer 140, and the multiple receiving cavities 142 on the first substrate 210 are in one-to-one correspondence with chip bonding areas on a circuit board.

Referring to FIG. 6, the electrodes 121 of the light-emitting chip 120 are disposed on the top surface of the light-emitting chip 120. When the light-emitting chip 120 is placed in the corresponding receiving cavity 142, the bottom surface of the light-emitting chip 120 is attached to the bottom of the corresponding receiving cavity 142 and contacted with the supporting layer 140. In actual applications, if the light-emitting chip 120 is disposed in such a way, a subsequent operation generally includes placing a circuit board above the light-emitting chip 120 directly, so that the light-emitting chip 120 can be fixed onto and connected with a circuit directly through a manner of fixing. When the circuit board fixed with the light-emitting chip is picked up, the light-emitting chip 120 can be picked up together with the circuit board. As such, transferring of the light-emitting chip 120 can be completed.

In these implementations, a height H of each of the multiple receiving cavities 142 is less than or equal to a height of each of the light-emitting chips 120.

Referring to FIG. 4 to FIG. 6, since the transient-substrate assembly is used to temporarily carry the light-emitting chips 120, the light-emitting chips 120 in the transient-substrate assembly are further required to be transferred onto other circuit boards in a subsequent production process, and therefore the height of each of the multiple receiving cavities 142 is required to be greater than or equal to the height of each of the light-emitting chips 120 to facilitate transferring of the light-emitting chips 120.

The transient-substrate assembly is provided in these implementations. The transient-substrate assembly includes the first substrate 210, the supporting layer 140, and the light-emitting chips 120. The supporting layer 140 is fixed on the first substrate 210, and defines the multiple receiving cavities 142 isolated from one another and the at least one opening 150 that extends through the top surface and the bottom surface of the supporting layer 140. The multiple receiving cavities 142 each have the opening away from the first substrate 210. The light-emitting chips 120 are respectively disposed in the multiple receiving cavities 142, where the light-emitting chip 120 is located at the bottom of the corresponding receiving cavity 142 and attached to the supporting layer 140, and the side surface of the light-emitting chip 120 and the internal side wall 141 of the corresponding receiving cavity 142 are separated by the gap. According to the transient-substrate assembly of the implementation, the supporting layer 140 is fixed on the first substrate 210 and defines the multiple receiving cavities 142 isolated from one another, and the light-emitting chips 120 are placed in their respective receiving cavities 142. As such, occurrence of relatively large displacement of the light-emitting chip 120 can be avoided because of fixing and constraint of the receiving cavity 142, which can protect the light-emitting chip 120, and thus improving yield of transferring of the light-emitting chips 120.

### In Other Implementations of the Disclosure

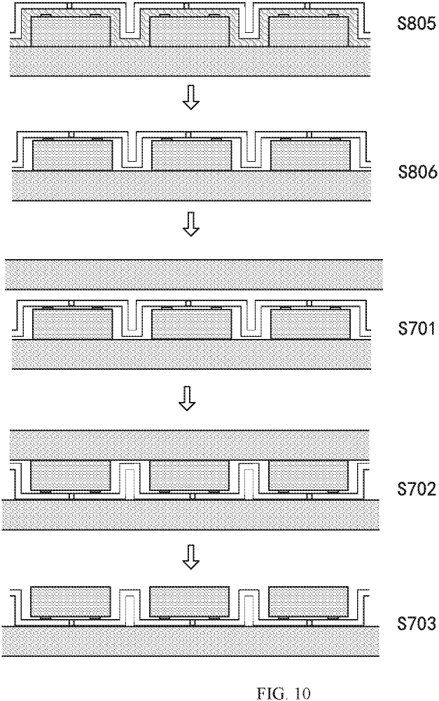

In order to facilitate understanding how to manufacture a transient-substrate assembly of implementations of the disclosure, a manufacturing method of the transient-substrate assembly is provided in these implementations. For details of operations of the manufacturing method of the transient-substrate assembly and schematic diagrams of products corresponding to the operations, reference can be made to FIG. 7 and FIG. 10. The manufacturing method of the transient-substrate assembly includes the following.

At S701, the first substrate 210 is provided.

The first substrate 210 is provided and placed above the supporting layer 140 of an array-substrate assembly, and the first substrate 210 can be the same as or different from the second substrate 110.

At S702, the first substrate 210 is fixed onto the supporting layer 140.

The supporting layer 140 defines the multiple receiving cavities 142 isolated from one another, a surface of the supporting layer 140 fixed on the first substrate 210 is away from an opening of each of the multiple receiving cavities 142, and the supporting layer 140 further defines at least one opening 150 extending through a top surface and a bottom surface of the supporting layer 140. As for a structure of the supporting layer 140, reference can be made to FIG. 1 to FIG. 6.

At S703, the light-emitting chips 120 are placed into the multiple receiving cavities 142.

The light-emitting chip 120 placed is located at a bottom of a corresponding receiving cavity 142 and attached to the supporting layer 140, and a side surface of the light-emitting chip 120 and an internal side wall 141 of the corresponding receiving cavity 142 are separated by a gap. The light-emitting chip 120 is placed into the corresponding receiving cavity 142 to fix and constrain the light-emitting chip 120, and it is considered that the light-emitting chip 120 is further required to be taken out from the corresponding receiving cavity 142 during subsequent transferring, and therefore the light-emitting chip 120 and the internal side wall 141 of the corresponding receiving cavity 142 need to be separated by a certain gap, thereby avoiding damage to the light-emitting chip 120 when picking up the light-emitting chip 120.

In these implementations, fixing the first substrate 210 onto a surface of the supporting layer 140 opposite to another surface of the supporting layer 140 facing an opening of each of the multiple receiving cavities 142 includes the following. An adhesive layer is disposed fixedly onto the first substrate 210. The first substrate 210 is fixed onto the supporting layer 140 through the adhesive layer.

In order to fix the first substrate 210 onto the supporting layer 140, the first substrate 210 needs to be preprocessed. The preprocessing includes, but is not limited to, disposing fixedly the adhesive layer onto the first substrate 210, or fixing the first substrate 210 onto the supporting layer 140 through bonding. A manner for forming the adhesive layer includes, but is not limited to, coating an adhesive layer, or adhering of a thin film.

In these implementations, before fixing the first substrate 210 onto a surface of the supporting layer 140 opposite to another surface of the supporting layer 140 facing an opening of each of the multiple receiving cavities 142, the method further includes the following. A sacrificial layer 130 among the supporting layer 140, the light-emitting chips 120, and a second substrate 110 is removed, where the supporting layer 140 is separated from the light-emitting chips 120 and the second substrate 110 through the sacrificial layer 130.

A manner of removal of the sacrificial layer 130 can be determined according to a characteristic of the sacrificial layer 130. For example, if the sacrificial layer 130 is a chemical debonding layer, the array-substrate assembly is soaked into a corresponding chemical solvent, the chemical solvent enters from the opening 150 and etches the sacrificial layer 130, and residuals produced by etching the sacrificial layer 130 are discharged through the opening 150. It can be understood that, after removing the sacrificial layer 130, the supporting layer 140 naturally falls under action of gravity and then is attached to the light-emitting chip 120. As for a schematic diagram illustrating removal of the sacrificial layer 130, reference can be made to operations at S805 and S806 in FIG. 10.

Since the sacrificial layer 130 is disposed on the light-emitting chips 120 and the second substrate 110 and the sacrificial layer 130 is provided to protect the light-emitting chips 120 under the sacrificial layer 130, and thus, the supporting layer 140 is required to be completely separated from the light-emitting chips 120 and the second substrate 110 through the sacrificial layer 130.

In these implementations, the sacrificial layer 130 defines a groove 131 between two adjacent light-emitting chips 120, and a side wall 141 of the receiving cavity 142 is filled in at least part of the groove 131.

The supporting layer 140 is formed on the sacrificial layer 130, and therefore, the side wall 141 of the receiving cavity 142 of the supporting layer 140 can be formed by filling the supporting layer 140 in the groove 131 defined on the sacrificial layer 130.

In these implementations, a thickness of the sacrificial layer 130 is greater than or equal to 0.1 µm, and less than or equal to 100 µm.

In these implementations, on condition that electrodes 121 of the light-emitting chip 120 are between the supporting layer 140 and the light-emitting chip 120, the thickness of the sacrificial layer 130 is greater than a height of each of the electrodes 121.

To avoid damage to the light-emitting chip 120 due to contact between the supporting layer 140 and the electrodes 121 of the light-emitting chip 120 during forming of the supporting layer 140, the thickness of the sacrificial layer 130 is greater than the height of each of the electrodes 121 if the electrodes 121 of the light-emitting chip 120 are located between the supporting layer 140 and the light-emitting chip 120, thereby ensuring that the supporting layer 140 is completely separated from the light-emitting chip 120.

In these implementations, removing the sacrificial layer includes at least one of: removing the sacrificial layer by irradiating a preset electromagnetic wave, removing the sacrificial layer by heating the sacrificial layer to a preset temperature, or removing the sacrificial layer by using a preset chemical reagent.

Optionally, the sacrificial layer includes, but is not limited to, a photolytic adhesive layer, a pyrolytic adhesive layer, or a chemical debonding layer, and therefore, the above methods can be respectively used to remove the photolytic adhesive layer, the pyrolytic adhesive layer, or the chemical debonding layer.

In these implementations, before removing the sacrificial layer 130, the method further includes the following.

At S801, the second substrate 110 is provided.

At S802, the light-emitting chips 120 are disposed onto the second substrate 110.

At S803, the sacrificial layer 130 is formed on the light-emitting chips 120 and a surface of the second substrate 110 disposed with the light-emitting chips 120.

At S804, the supporting layer 140 is formed on the sacrificial layer 130.

At S805, the opening 150 is defined on the supporting layer 140.

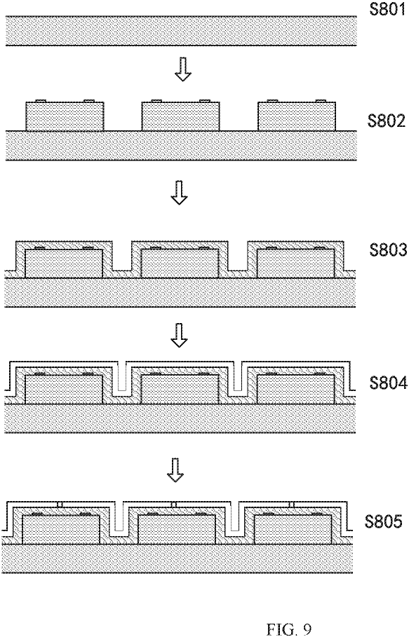

Referring to FIG. 8 and FIG. 9, in the operations at S801, the second substrate 110 is used to carry the multiple light-emitting chips 120. Optionally, the second substrate 110 includes, but is not limited to, a sapphire substrate, a gallium-selenide substrate, or a silicon substrate.

In the operations at S802, the multiple light-emitting chips 120 are fixed on the second substrate 110. The multiple light-emitting chips 120 are generally arranged on the second substrate 110 in an array according to a certain rule. The light-emitting chips 120 of these implementations include, but are not limited to, light-emitting chips 120 that are transferred onto the second substrate 110, or light-emitting chips 120 that are grown directly on the second substrate 110. The light-emitting chips 120 include, but are not limited to, multiple-color light-emitting chips 120 (e.g., RGB light-emitting chips 120), or single-color light-emitting chips 120, where structures and placement of light-emitting chips 120 are not limited in the disclosure.

For the operations at S803, the sacrificial layer 130 is required to be completely covered on the second substrate 110 and the light-emitting chips 120. The sacrificial layer 130 defines a groove 131 between two adjacent light-emitting chips 120, and each of the light-emitting chips 120 is surrounded by grooves 131. For ensuring that the groove 131 can be formed, a thickness of the sacrificial layer 130 on the side surface of the light-emitting chip 120 is required to be less than a half of a size of a gap between two adjacent light-emitting chips 120, and thicknesses of other parts of the sacrificial layer 130 are not limited but generally do not exceed a half of a thickness of the light-emitting chip 120. If the electrodes 121 of the light-emitting chip 120 are located at the top of the light-emitting chip 120, a part of the sacrificial layer 130 on the light-emitting chip 120 further needs to have a thickness that allows the electrodes 121 to be completely covered. The sacrificial layer 130 is removed during subsequent operations, and therefore the sacrificial layer 130 may include, but is not limited to, a photolytic adhesive layer, a pyrolytic adhesive layer, or a chemical debonding layer. The photolytic adhesive layer is made of a photosensitive material and can be removed under irradiation of a specific-wavelength light. The pyrolytic adhesive layer is made of a thermosensitive material and can be removed by heating the pyrolytic adhesive layer to a preset temperature. The chemical debonding layer is made of a material that can be removed by a specific chemical substance.

For the operations at S804, the supporting layer 140 is completely covered on the sacrificial layer 130. The supporting layer 140 is filled in at least part of the groove 131 of the sacrificial layer 130, to form a concave structure (as side walls 141) between two adjacent light-emitting chips 120. The supporting layer 140 is used to protect and fix the light-emitting chips 120, and therefore, the supporting layer 140 is required to have a certain support force and a certain structural strength. A thickness of the supporting layer 140 is not limited in these implementations, as long as the supporting layer 140 has a required structural strength. Generally, the thickness of the supporting layer 140 includes, but is not limited to, 0.5 µm, 1 µm, 2 µm, 5 µm, etc.

For the operations at S805, since the sacrificial layer 130 is required to be removed in subsequent operations, the opening 150 is required to be defined on the supporting layer 140. When removing the sacrificial layer 130, etchant can enter through the opening 150, and residuals of the sacrificial layer 130 can be discharged through the opening 150. It is to be noted that, the opening 150 can be defined on any part of the supporting layer 140, but in order to improve yield and avoid damage to the light-emitting chip 120, the opening 150 is generally defined on a part of the supporting layer 140 which is not overlapped with the electrodes 121 of the light-emitting chip 120. A shape of the opening 150 is not specifically limited in the disclosure. The opening 150 may be in a shape of square, rectangle, circle, etc. As for the opening 150, if the opening 150 is defined above the light-emitting chip 120, a size (or an area) of the opening 150 is required not to be greater than a half of a size (or an area) of the light-emitting chip 120; if the opening 150 is defined between two adjacent light-emitting chips 120, a width of the opening 150 is required not to be greater than a size of a gap between two adjacent light-emitting chips 120.

In these implementations, the sacrificial layer 130 and the supporting layer 140 may be formed through ion beam deposition (IBD). The thickness of the sacrificial layer 130 and the thickness of the supporting layer 140 can be controlled easily through the IBD. Moreover, when the sacrificial layer 130 and the supporting layer 140 are formed, it is easy for ionic deposits to be covered in the gap between two adjacent light-emitting chips 120, to form the groove 131 and the side wall 141 filled in the groove 131.

In these implementations, a manner for defining the opening 150 on the supporting layer 140 includes: forming an etching pattern on the supporting layer 140, and forming the opening 150 in communication with the sacrificial layer 130 by etching the supporting layer 140.

Since the supporting layer 140 has a certain support performance and a relatively high structural strength, an etching pattern can be formed on the supporting layer 140 through patterning, and the opening 150 can be formed by etching a part of the supporting layer 140 specified by the etching pattern when etched.

In these implementations, before placing the light-emitting chips 120 into the multiple receiving cavities 142 after fixing the first substrate 210 onto a surface of the supporting layer 140 opposite to another surface of the supporting layer 140 facing an opening of each of the multiple receiving cavities 142, the method further includes flipping over the second substrate 110 and the first substrate 210.

Referring to FIG. 9 and FIG. 10, the first substrate 210 is fixed onto the supporting layer 140. In actual production, it is considered that the light-emitting chips 120 are required to be stripped off from the second substrate 110, and therefore, the whole assembly is required to be flipped along a certain direction after the first substrate 210 is covered on the supporting layer 140.

In these implementations, placing the light-emitting chips 120 into the multiple receiving cavities 142 includes stripping off the light-emitting chips 120 from the second substrate 110.

The light-emitting chip 120 on the second substrate 110 is stripped off, and the light-emitting chip 120 naturally falls into a corresponding receiving cavity 142 of the supporting layer 140 under action of gravity. A manner for stripping off the light-emitting chip 120 includes, but is not limited to, stripping off the light-emitting chip 120 by disintegrating gallium nitride (GaN) of the bottom of the light-emitting chip 120 with a laser lift off (LLO) device.

As can be seen from the above implementations, according to the transient-substrate assembly and the manufacturing method thereof provided in the disclosure, if the light-emitting chip 120 is stripped off from the second substrate 110 and then placed into a corresponding receiving cavity 142 of the supporting layer 140, the receiving cavity 142 can constrain displacement of the light-emitting chip 120 and fix the light-emitting chip 120, thereby avoiding occurrence of displacement of the light-emitting chip 120 when stripping off the light-emitting chip 120 or moving and transporting the transient-substrate assembly, and thus improving yield.

It is to be understood that the disclosure is not to be limited to the disclosed implementations. Those of ordinary skill in the art can make improvements or changes based on the above description, and all these improvements and changes should fall within the protection scope of the appended claims of this disclosure.

What is claimed is:

1. A transient-substrate assembly, comprising:
a first substrate;
a supporting layer fixed on the first substrate, wherein the supporting layer defines a plurality of receiving cavities isolated from one another and at least one opening that extends through a top surface and a bottom surface of the supporting layer, and the plurality of receiving cavities each have an opening away from the first substrate; and
light-emitting chips respectively disposed in the plurality of receiving cavities, wherein the light-emitting chip is located at a bottom of a corresponding receiving cavity and attached to the supporting layer, and a side surface of the light-emitting chip and a side wall of the corresponding receiving cavity are separated by a gap.

2. The transient-substrate assembly of claim 1, wherein the supporting layer is any one of: a silicon-dioxide layer, a silicon-nitride layer, or a metal layer.

3. The transient-substrate assembly of claim 1, wherein the opening defined on the supporting layer comprises at least one of:
a first opening defined on the supporting layer that corresponds to a bottom of each of the plurality of receiving cavities; or
a second opening defined on the supporting layer between two adjacent light-emitting chips.

4. The transient-substrate assembly of claim 3, wherein the first opening is between two electrodes of the light-emitting chip.

5. The transient-substrate assembly of claim 1, wherein the light-emitting chips each have a top surface and a bottom surface opposite to the top surface, electrodes of the light-emitting chip are disposed on the bottom surface of the light-emitting chip and attached to the supporting layer.

6. The transient-substrate assembly of claim 1, wherein the light-emitting chips each have a top surface and a bottom surface opposite to the top surface, electrodes of the light-emitting chip are disposed on the bottom surface of the light-emitting chip, the top surface of the light-emitting chip is attached to the supporting layer, and the plurality of receiving cavities on the first substrate are in one-to-one correspondence with chip bonding areas on a circuit board.

7. The transient-substrate assembly of claim 1, wherein a height of each of the plurality of receiving cavities is less than or equal to a height of each of the light-emitting chips.

8. A manufacturing method of a transient-substrate assembly, comprising:
providing a first substrate of the transient-substrate assembly;
fixing the first substrate onto a supporting layer of the transient-substrate assembly, wherein the supporting layer defines a plurality of receiving cavities isolated from one another, a surface of the supporting layer fixed on the first substrate is away from an opening of each of the plurality of receiving cavities, and the supporting layer further defines at least one opening extending through a top surface and a bottom surface of the supporting layer; and
placing light-emitting chips of the transient-substrate assembly into the plurality of receiving cavities respectively, wherein the light-emitting chip placed is located at a bottom of a corresponding receiving cavity and attached to the supporting layer, and a side surface of the light-emitting chip and a side wall of the corresponding receiving cavity are separated by a gap.

9. The manufacturing method of the transient-substrate assembly of claim 8, wherein fixing the first substrate onto the supporting layer of the transient-substrate assembly comprises:
disposing fixedly an adhesive layer onto the first substrate; and
fixing the first substrate onto the supporting layer through the adhesive layer.

10. The manufacturing method of the transient-substrate assembly of claim 8, wherein before fixing the first substrate onto the supporting layer of the transient-substrate assembly, the method further comprises:
removing a sacrificial layer among the supporting layer, the light-emitting chips, and a second substrate, wherein the supporting layer is separated from the light-emitting chips and the second substrate through the sacrificial layer.

11. The manufacturing method of the transient-substrate assembly of claim 10, wherein removing the sacrificial layer comprises at least one of:
removing the sacrificial layer by irradiating a preset electromagnetic wave;
removing the sacrificial layer by heating the sacrificial layer to a preset temperature; or
removing the sacrificial layer by using a preset chemical reagent.

12. The manufacturing method of the transient-substrate assembly of claim 10, wherein the sacrificial layer defines a groove between two adjacent light-emitting chips, and a side wall of two adjacent receiving cavities is filled in at least part of the groove.

13. The manufacturing method of the transient-substrate assembly of claim 10, wherein a thickness of the sacrificial layer is greater than or equal to 0.1 µm and less than or equal to 100 µm.

14. The manufacturing method of the transient-substrate assembly of claim 10, wherein on condition that electrodes of the light-emitting chip are between the supporting layer and the light-emitting chip, a thickness of the sacrificial layer is greater than a height of each of the electrodes.

15. The manufacturing method of the transient-substrate assembly of claim 10, wherein before removing the sacrificial layer, the method further comprises:
providing the second substrate;
disposing the light-emitting chips onto the second substrate;
forming the sacrificial layer on the light-emitting chips and a surface of the second substrate disposed with the light-emitting chips;
forming the supporting layer on the sacrificial layer; and
defining the at least one opening on the supporting layer.

16. The manufacturing method of the transient-substrate assembly of claim 15, wherein after fixing the first substrate onto the supporting layer of the transient-substrate assembly, the method further comprises:
flipping over the second substrate and the first substrate.

17. The manufacturing method of the transient-substrate assembly of claim 16, wherein placing the light-emitting chips of the transient-substrate assembly into the plurality of receiving cavities respectively comprises:
placing the light-emitting chip into a corresponding receiving cavity by stripping off the light-emitting chip from the second substrate after the second substrate and the first substrate are flipped over, wherein the light-emitting chip placed is attached to a bottom of the corresponding receiving cavity.

18. The manufacturing method of the transient-substrate assembly of claim 8, wherein the opening defined on the supporting layer comprises at least one of:
a first opening defined on the supporting layer that corresponds to a bottom of each of the plurality of receiving cavities; or
a second opening defined on the supporting layer between two adjacent light-emitting chips.

19. The manufacturing method of the transient-substrate assembly of claim 18, wherein the first opening is between two electrodes of the light-emitting chip.

20. The manufacturing method of the transient-substrate assembly of claim 8, wherein the light-emitting chips each have a top surface and a bottom surface opposite to the top surface, electrodes of the light-emitting chip are disposed on the bottom surface of the light-emitting chip and attached to the supporting layer.
